(19) United States
(12) Patent Application Publication
(10) Pub. No.: US 2024/0128975 A1
(43) Pub. Date: Apr. 18, 2024

(54) SIGNAL ISOLATION CIRCUIT

(71) Applicant: Mitsubishi Electric Corporation, Tokyo (JP)

(72) Inventors: Satoshi OJIKA, Chiyoda-ku, Tokyo (JP); Yu FUKUMOTO, Chiyoda-ku, Tokyo (JP)

(73) Assignee: Mitsubishi Electric Corporation, Tokyo (JP)

(21) Appl. No.: 18/278,011

(22) PCT Filed: Mar. 8, 2021
(86) PCT No.: PCT/JP2021/008980

§ 371 Date: Aug. 21, 2023

(51) Int. Cl. H03K 17/691; H03K 17/723

(52) U.S. Cl. CPC H03K 17/691; H03K 17/723; H03K 2017/9527

(57) ABSTRACT

The primary circuit and the secondary circuit are electrically insulated from each other by the transformer so as to operate at different reference potentials. The primary coil has a first end which is driven by an input signal. The primary coil has a second end which is driven by an output signal of the delay element. An induced voltage of the secondary coil is input to the retention element, which, in turn, switches and retains a value of the output signal, based on the induced voltage of the secondary coil.

### TECHNICAL FIELD

The present disclosure relates to a signal isolation circuit.

### BACKGROUND ART

In order to transmit and receive signals between circuits having different potentials, an isolation element is necessary. In general, a photocoupler a digital isolator, an isolation amplifier, etc., sealed in an integrated circuit (IC) package, are used as the isolation element.

PTL 1 discloses one example of a digital isolator circuit scheme. According to the scheme disclosed in PTL 1, a transmitter circuit and a receiver circuit are coupled together by an isolation barrier. For example, a pulse transformer (a pulse transformer) or a capacitance coupling is used as the isolation barrier, thereby ensuring electrical insulation. The transmitter and receiver circuits are composed of various circuit elements. For example, the circuit scheme disclosed in PTL 1 requires a clock signal, a digital differentiator circuit, a tri-state buffer, an analog bias circuit, and an analog comparator, etc. These components can all be mounted on an IC, thereby, theoretically, forming a compact, fast signal isolation circuit.

### CITATION LIST

### Patent Literature

PTL 1: Japanese National Patent Publication No. H8-507908

### SUMMARY OF INVENTION

### Technical Problem

For special applications, there are cases where there is no existing IC that has sufficient performance and has been well proven, or where, due to small production volumes of a device, the process and cost for producing a IC dedicated to the device cannot ensured. In such cases, an isolation amplifier circuit may be used which is a combination of a general-purpose IC and discrete parts and produced using a printed circuit board. However, thus configured circuit board has a large size and is not applicable to devices that require a large number of signal isolation circuits.

Therefore, an object of the present disclosure is to provide a compact, fast signal isolation circuit that adopts only general-purpose elements and can transmit and receive signals while ensuring isolation between electronic circuits having different reference potentials.

### Solution to Problem

A signal isolation circuit according to the present disclosure includes: an input terminal to receive a digital input signal; a primary circuit which includes a delay element for delaying the input signal; a secondary circuit which includes a retention element for retaining a digital output signal; an output terminal to output the output signal; and a transformer which includes a primary coil connected to the primary circuit and a secondary coil connected to the secondary circuit. The primary circuit and the secondary circuit are electrically insulated from each other by the transformer so as to operate at different reference potentials. The primary coil has a first end which is driven by an input signal. The primary coil has a second end which is driven by an output signal of the delay element. An induced voltage of the secondary coil is input to the retention element, and the retention element switches and retains a value of the output signal, based on the induced voltage of the secondary coil.

### Advantageous Effects of Invention

In the signal isolation circuit according to the present disclosure, the first end of the primary coil is driven by the input signal. The second end of the primary coil is driven by the output signal of the delay element. According to the present disclosure, a compact, fast signal isolation circuit can be provided which uses only general-purpose elements and allows transmission and reception of signals between electronic circuits having different reference potentials, while ensuring isolation between the electronic circuits.

### BRIEF DESCRIPTION OF DRAWINGS

FIG. 1 is a diagram depicting a configuration of a signal isolation circuit 1 according to Embodiment 1.

FIG. 2 is a diagram illustrating one example configuration of a retention element 8.

FIG. 3 is a diagram showing another example configuration of the retention element 8.

FIG. 4 is a diagram illustrating one example configuration of a delay element 7.

FIG. 5 is a diagram showing another example configuration of the delay element 7.

FIG. 6 is a diagram depicting a line pattern, on a printed circuit board, configuring a transformer 3.

FIG. 7 is a diagram depicting a configuration of a signal isolation circuit 1A according to Embodiment 2.

FIG. 8 is a diagram depicting a configuration of a signal isolation circuit 1B according to Embodiment 3.

FIG. 9 is a diagram depicting a configuration of a signal isolation circuit 1C according to Embodiment 4.

### DESCRIPTION OF EMBODIMENTS

Hereinafter, embodiments will be described, with reference to the accompanying drawings.

### Embodiment 1

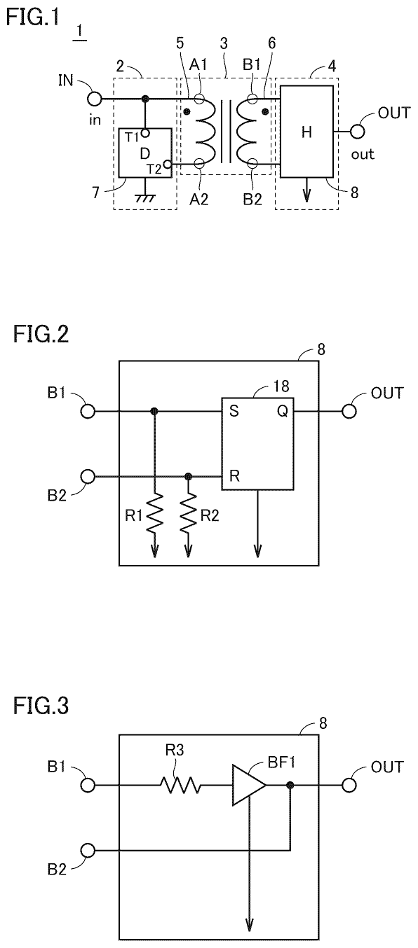

FIG. 1 is a diagram depicting a configuration of a signal isolation circuit 1 according to Embodiment 1.

The signal isolation circuit 1 includes a primary circuit 2, a secondary circuit 4, and a transformer 3.

The signal isolation circuit 1 includes one input terminal IN and one output terminal OUT. The signal isolation circuit 1 is configured for the purposes of correctly transmitting signals even if the input terminal IN and the output terminal OUT have different reference potentials.

The input terminal IN receives a digital input signal in. The output terminal OUT outputs a digital output signal out.

The primary circuit 2 includes a delay element 7 for delaying the input signal in.

The secondary circuit 4 includes a retention element 8 for retaining the output signal out.

The transformer 3 includes a primary coil 5 connected to the primary circuit 2, and a secondary coil 6 connected to the secondary circuit 4.

The primary circuit 2 and the secondary circuit 4 are coupled together by the transformer 3, and the primary circuit 2 and the secondary circuit 4 are thereby electrically insulated from each other so that they can operate at different reference potentials.

The primary coil 5 of the transformer 3 has a first end A1 which is driven by the input signal in. The delay element 7 delays the input signal in by a unique delay time dt and outputs a delay signal. The primary coil 5 of the transformer 3 has a second end A2 which is driven by the delay signal output from an output terminal T2 of the delay element 7. Doing so allows only changes in logic of the input signal in to be transmitted to the secondary circuit 4.

For example, the output signal of the delay element 7 is at Low level since the input signal In has changed from Low level to High level until the delay time dt has elapsed. As a result, the first end A1 of the primary coil 5 of the transformer 3 is driven at High level and the second end A2 is driven at Low level, which positively excites the transformer 3. After the elapse of the delay time dt, the output signal of the delay element 7 changes to High level, and the ends A1 and A2 of the primary coil 5 of the transformer 3 are driven at High level. Consequently, the transformer 3 is no longer excited.

Similarly, when the input signal in changes from High level to Low level, the output of the delay element 7 is maintained at High level until the delay time dt has elapsed. Thus, the first end A1 of the primary coil 5 of the transformer 3 is driven to Low level and the second end A2 is driven to High level. Consequently, the transformer 3 is negatively excited. After the elapse of the delay time dt, the output signal of the delay element 7 changes to Low level and the ends A1 and A2 of the primary coil 5 of the transformer 3 are driven at Low level. Consequently, the transformer 3 is no longer excited.

Doing so allows the transformer 3 to be excited only by the delay time dt of the delay element 7, independent of a pulse width of the input signal in. Even if the input signal in has a long pulse width, a VT (voltage×time) product applied to the transformer 3 can be reduced by designing the delay time dt to be short. In general, the greater the VT product is, the greater the dimensions and mass of the transformer. Thus, by reducing the delay time dt of the delay element 7 as short as possible, a compact and lightweight transformer 3 can be provided, without limiting the pulse width of the input signal in.

The secondary coil 6 of the transformer 3 is connected to the retention element 8. The output of the retention element 8 is connected to the output terminal OUT. The retention element 8 is configured to switch and retain the value of the output signal out, based on an induced voltage produced at the secondary coil 6.

As the transformer 3 is positively excited, a positive voltage is produced at the secondary coil 6. The retention element 8 outputs High level (a first logical value) if the induced voltage of the secondary coil 6 of the transformer 3 is greater than a positive threshold THP.

As the transformer 3 is negatively excited, a negative voltage is produced at the secondary coil 6. The retention element 8 outputs Low level (a second logical value) if the induced voltage of the secondary coil 6 of the transformer 3 is less than a negative threshold THN.

When the transformer 3 is not excited, the induced voltage of the secondary coil 6 is greater than or equal to the negative threshold THN and less than or equal to the positive threshold THP. The retention element 8 is configured to retain the previous output value if the induced voltage of the secondary coil 6 of the transformer 3 is greater than or equal to the negative threshold THN and less than or equal to the positive threshold THP.

Such an operation enables an operation in which the input signal changes to High level in response to which the output signal out changes to High level, and the input signal in changes to Low level in response to which the output signal out changes to Low level. Since the primary circuit 2 and the secondary circuit 4 are insulated from each other by the transformer 3, the digital signal can be transmitted between the insulated circuits.

Next, elements of the signal isolation circuit 1 according to Embodiment 1 will be described in detail.

(Retention Element)

The retention element 8 may output High level if the induced voltage of the secondary coil 6 of the transformer 3 is greater than the positive threshold THP, output Low level if the induced voltage of the secondary coil 6 of the transformer 3 is less than the negative threshold THN, or otherwise retain the output level. Note that, in the present embodiment, the High level of the input signal in and the output signal out is one example of the first logical value (logic 1), and the Low level is one example of the second logical value (logic 0). Conversely, the Low level of the input signal in and the output signal out may be the first logical value (the logic 1) and the High level may be the second logical value (the logic 0).

For example, the retention element 8 that is configured of a hysteresis comparator circuit or a Schmitt trigger buffer circuit has the following problems. The hysteresis comparator is an analog circuit. If a Schmitt trigger buffer circuit is used, an analog circuit needs to be used to generate and apply an appropriate bias voltage. Thus, configuring the retention element 8 with these circuits requires at least an analog circuit, making the size reduction and high-speed operation difficult.

In the present embodiment, the retention element 8 is configured of a digital circuit.

FIG. 2 is a diagram illustrating one example configuration of the retention element 8.

The retention element 8 includes a RS flip-flop 18, a first pull-down resistor R1, and a second pull-down resistor R2.

The first pull-down resistor R1 is disposed between the ground and a first end B1 of the secondary coil 6 of the transformer 3. The second pull-down resistor R2 is disposed between the ground and a second end B2 of the secondary coil 6 of the transformer 3. The voltages at the ends B1 and B2 of the secondary coil 6 of the transformer 3 are pulled down by the first pull-down resistor R1 and the second pull-down resistor R2, respectively.

The first end B1 of the secondary coil 6 of the transformer 3 is connected to a set terminal S of the RS flip-flop 18. The second end B2 of the secondary coil 6 of the transformer 3 is connected to a reset terminal R of the RS flip-flop 18.

The RS flip-flop 18 has an output terminal Q connected to the output terminal OUT. As the transformer 3 is positively excited, the set terminal S is activated, which causes the output terminal Q of the RS flip-flop 18 to be at High level. As the transformer 3 is negativity excited, the reset terminal R is activated, which causes the output terminal Q of the RS flip-flop 18 to be at Low level. When the transformer 3 is not excited, The secondary coil 6 has substantially zero induced voltage. Thus, the input terminals S and R of the RS flip-flop 18 are maintained at Low level by the pull-down resistors R1 and R2 pulling down the voltages. As a result, the RS flip-flop 18 retains the previous output.

Note that the circuit structure of FIG. 2 is one example configuration if the RS flip-flop 18 is used, and it goes without saying that any modification may be made to the circuit structure as appropriate, insofar as the retention element 8 performs the same operation.

FIG. 3 is a diagram showing another example configuration of the retention element 8.

The retention element 8 includes an amplifier element BF1 and a resistor R3.

An input of the amplifier element BF1 receives the voltage at the first end B1 of the secondary coil 6. An output of the amplifier element BF1 is connected to the output terminal OUT.

The resistor R3 is disposed between the amplifier element BF1 and the first end B1 of the secondary coil 6. The first end B1 of the secondary coil 6 of the transformer 3 is connected to an input terminal of the amplifier element BF1 via the resistor R3. The second end B2 of the secondary coil 6 of the transformer 3 is connected to an output terminal of the amplifier element BF1. A positive feedback circuit is configured by the output of the amplifier element BF1 driving the second end B2 of the secondary coil. If the transformer 3 is not excited, the output logic is retained.

When the output of the amplifier element BF1 is at Low level and the transformer 3 is positively excited, the input of the amplifier element BF1 changes from Low level to High level, and the output of the amplifier element BF1 also changes to High level. In this state, if the transformer 3 is de-energized, the amplifier element BF1 maintains the output at High level.

When the output of the amplifier element BF1 is at High level and the transformer 3 is negativity excited, the input of the amplifier element BF1 changes from High level to Low level, and the output of the amplifier element BF1 also changes to Low level. In this state, if the transformer 3 is de-energized, the amplifier element BF1 maintains the output at Low level.

The resistor R3 is inserted, as needed, to reduce the current and the voltage that are applied to the input terminal of the amplifier element BF1 when the transformer 3 is excited. While the resistor R3 may be omitted if there is no problem with the circuit operation, providing the resistor R3 having an appropriate resistance value can reduce the current flowing through the circuit, allowing for the use of small-rated parts.

The amplifier element BF1 may have a gain above “1” to establish a positive feedback, and a logic buffer for digital signal may be employed, in addition to an analog amplifier circuit. The use of a logic buffer can reduce the circuit size, allowing for high integration.

Note that the circuit structure of FIG. 3 is one example for using the amplifier element BF1 to configure the positive feedback. It goes without saying that an appropriate change can be made to the circuit structure insofar as the retention element 8 performs the same operation.

(Delay Element)

The delay element 7 may add a unique delay to the input signal in, as described above. For example, the delay element 7 may be configured of a delay line or a transmission line.

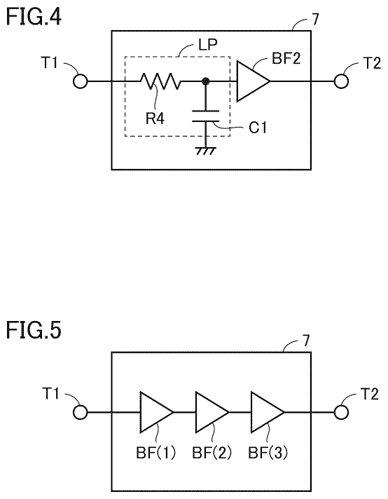

FIG. 4 is a diagram illustrating one example configuration of the delay element 7.

The delay element 7 includes a low-pass filter LP and an amplifier element BF2.

The low-pass filter LP receives the input signal in from an input terminal T1 connected to the input terminal IN. The low-pass filter LP is implemented by an RC filter circuit which exhibits first-order delay characteristics and includes a resistor R4 and a capacitor C1. Alternatively, the low-pass filter LP may be implemented by other circuit (e.g., an RL filter) that exhibits the characteristics similar to the RC filter circuit or a filter (e.g., an RLC filter) exhibiting second-order delay characteristics.

The amplifier element BF2 is disposed between the output of the low-pass filter LP and the output terminal T2 connected to the second end A2 of the secondary coil 5. The amplifier element BF2 is used to waveform reshaping and ensure the driving force. However, besides an analog amplifier circuit having a gain above “1,” a logic buffer for digital signal may be employed. The use of a logic buffer allows for use of the same element as the retention element 8, and is thus suitable for integration. The amplifier element BF2 also has a unique delay, and is thus, designed so that the time dt, which is the sum of a delay time of the amplifier element BF1 and a delay time of the low-pass filter LP, is a desired delay time.

If waveform reshaping and ensuring of the driving force are not necessary, the amplifier element BF1 may be omitted, and the delay element 7 may be configured of the low-pass filter LP only.

FIG. 5 is a diagram showing another example configuration of the delay element 7.

The delay element 7 includes three stages of amplifier elements BF(1), BF(2), and BF(3).

The delay element 7 is designed so that the time dt, which is the sum of the delay times of the three stages of the amplifier elements BF(1), BF(2), and BF(3), is a desired delay time.

The configuration of FIG. 5 actively uses the delays of the amplifier elements. Since an amplifier element, in general, has a short delay time, amplifier elements can be cascaded (cascade-connected) as appropriate and used so that a desired delay time can be obtained. While the delay element 7 of FIG. 5 includes three stages of amplifier elements, it goes without saying that the number of stages of amplifier elements may be changed to any one or more stages insofar as a desired circuit operation is achieved. The amplifier element is used to add a delay to the signal and ensure the driving force. An analog amplifier circuit having a gain above “1” or a logic buffer for digital signal can also be employed. The use of a logic buffer allows for use of the same element as the retention element 8, and is thus suitable for integration.

The temporal width of a pulse during which the transformer 3 is excited depends on the delay time dt of the delay element 7, as described above. The shorter the pulse period is, the more the transformer 3 can be reduced in size. However, if the pulse period is too short, the secondary circuit 4 does not respond, and signal transmission fails. Considering changes in characteristics due to variations in parts, variations in temperature, and variations in voltage, etc., preferably, the delay element 7 is designed to have the delay time dt that is about twice to ten times the response time of the secondary circuit 4.

As described above, minimum necessary elements for the configuration and operation of the signal isolation circuit 1 according to Embodiment 1 have been described. Of course, appropriate other elements can be added, insofar as the function of the signal isolation circuit 1 is not impaired.

While the delay element 7 and the retention element 8 have been described as being configured with individual parts, they may be configured as an integrated circuit such as an IC, or may be configured with micro controllers, programs on a processor such as a central processing unit (CPU), programmable logic devices (such as PLDs, complex programmable logic devices (CPLDs), or field programmable gate arrays (FPGA)).

While the delay element 7 has been described as having a unique delay time that depends on characteristics of the device, the delay element 7 may be configured with a flip-flop that delays a signal, in synchronization with a clock signal, or a counter that counts clock pulses and generates a delay time. The numeric values and mathematical formulas described above are merely one suitable example for the purposes of illustration, and may be changed as appropriate.

The transformer 3 can be configured of a transformer in which a copper wire is wound around a general magnetic core. Alternatively, the transformer 3 can be configured of a line pattern on a printed circuit board. In this case, the part count can be reduced.

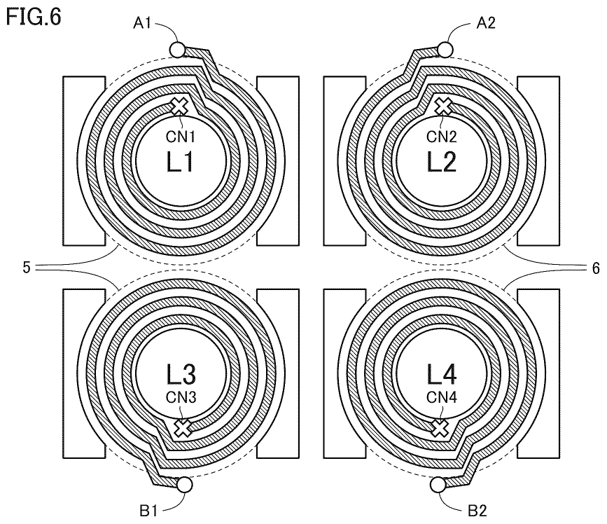

FIG. 6 is a diagram depicting a line pattern, on the printed circuit board, configuring the transformer 3. As shown in FIG. 6, line patterns L1 through L4 may have spiral shapes. For example, the primary coil 5 includes the line pattern L1 and the line pattern L2. The secondary coil 6 can include the line pattern L3 and the line pattern L4. L1 through L4 are the uppermost layer to the lowermost layer in the listed order. In other words, the uppermost layer is L1, L2 is the layer immediately below L1, L3 is the layer immediately below L2, and L4 is the layer immediately below L4.

The first end A1 of the primary coil 5 is disposed on the line pattern L1. The second end A2 of the primary coil 5 is disposed on the line pattern L2. The first end B1 of the secondary coil 6 is disposed on the line pattern L3. The second end B2 of the secondary coil 6 is disposed on the line pattern L4. The upper layers and the lower layers are connected together by interlayer connections CN1 through CN4.

While FIG. 6 illustrates the transformer 3 is configured with four interconnect layers, the transformer 3 can be configured with two layers, each layer being formed of two windings. While the transformer 3 may have an air core coil if sufficient inductance is ensured, the dimensions of the transformer 3 can be reduced by sandwiching the printed circuit board with magnetic cores.

### Embodiment 2

As described in Embodiment 1, the configuration of FIG. 1, ideally, excites the transformer 3 only upon changes in input signal in, and, consequently, a digital signal is transmitted between the circuits insulated from each other. In practice, however, the circuit elements vary in characteristics, and, sometimes, enter an unintended metastable state.

Assume that the input terminal IN has a higher internal impedance than the delay element 7. If the circuit activates when the initial state of the input signal in is High level and the initial state of the output of the delay element 7 is Low level, a large current flows through the primary coil 5 of the transformer 3, which reduces the voltage of the input signal in, sometimes, below the input voltage threshold (the positive threshold THP) of the delay element 7. Normally, the logic of the delay element 7 is the same as the logic of the input signal in with a certain delay time dt, but, in this state, the input signal in and the delay element 7 continue to differ in logic, causing the primary coil 5 of the transformer 3 to continue to be excited. Once this state takes place, the circuit is in equilibrium, and it is difficult to naturally resolve this state, not only failing to perform signal transmission correctly but also allowing a large current to continue to flow through the primary coil 5 having a low DC resistance, resulting in excessive power consumption. The primary coil 5 may burn out if a state continues in which the amount of heat generated continues to be above the amount of heat released.

The signal isolation circuit 1A according to Embodiment 2 can avoid such a metastable state.

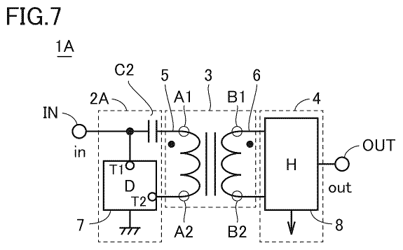

FIG. 7 is a diagram depicting a configuration of the signal isolation circuit 1A according to Embodiment 2.

The signal isolation circuit 1A according to Embodiment 2 differs from the signal isolation circuit 1 according to Embodiment 1 in that the signal isolation circuit 1A according to Embodiment 2 includes a primary circuit 2A that includes a capacitor C2.

The capacitor C2 is disposed between an input terminal IN and a first end A1 of a primary coil 5 of a transformer 3, forming an alternating-current (AC) coupled circuit. The capacity of the capacitor C2 is selected so that the capacitor C2 passes therethrough a pulse sufficient for exciting the transformer 3 in normal operation and the signal transmission is established.

For example, preferably, the capacity of the capacitor C2 is 10 Ω/V or greater, where Q is an amount of flow of electric charge due to the transformer 3 excitation pulse, and V is a supply voltage for the circuit.

When the primary coil 5 continues to be excited, the insertion of the capacitor C2 has advantageous effects of reducing the voltage charged to the capacitor C2 and applied to the primary coil 5 and preventing the current flow. This allows the metastable state as described above can be resolved over time if it occurs, and a highly reliable signal isolation circuit can be implemented.

While the capacitor C2 is connected to the first end A1 of the primary coil 5 in FIG. 7, the present disclosure is not limited thereto. The capacitor C2 may be connected to the second end A2 of the primary coil 5, or the capacitor C2 may be disposed at a point of the primary coil 5. It goes without saying that the similar advantageous effects can be obtained by, alternatively, disposing multiple capacitors at these locations.

### Embodiment 3

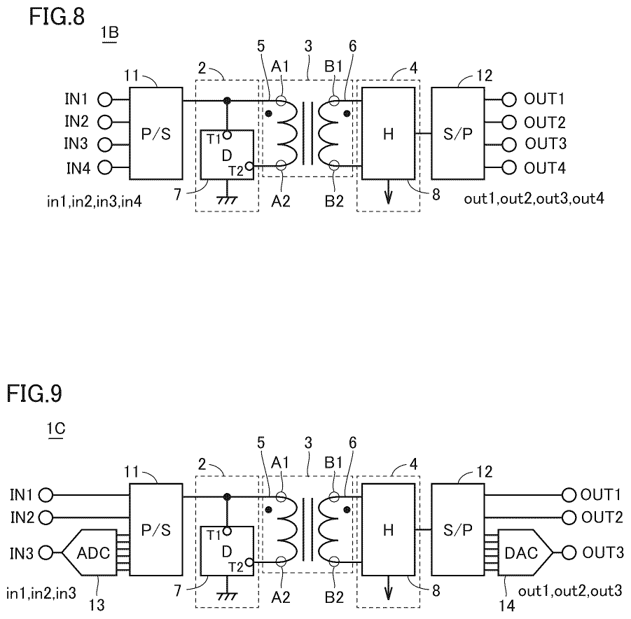

FIG. 8 is a diagram depicting a configuration of a signal isolation circuit 1B according to Embodiment 3.

The signal isolation circuit 1B of FIG. 8 differs from the signal isolation circuit 1 of FIG. 1 with respect to the following:

Input terminals IN1, IN2, IN3, and IN4 receive parallel digital input signals in1, in2, in3, and in4. Output terminals OUT1, OUT2, OUT3, and OUT4 output parallel digital output signals out1, out2, out3, and out4.

In addition to the configuration of the signal isolation circuit 1 according to Embodiment 1, the signal isolation circuit 1B includes a parallel-to-serial converter circuit (P/S) 11 and a serial-to-parallel converter circuit (S/P) 12.

The parallel-to-serial converter circuit (P/S) 11 is connected to the input terminal IN of the signal isolation circuit 1.

The serial-to-parallel converter circuit (S/P) 12 is connected to the output terminal OUT of the signal isolation circuit 1. The parallel-to-serial converter circuit (P/S) 11 and the serial-to-parallel converter circuit (S/P) are electrically insulated from each other.

The parallel-to-serial converter circuit (P/S) 11 converts the parallel digital input signals in1 through in4 into serial signals in1 through in4 input to the input terminals IN1 through IN4 by time division multiplexing (serialization), and outputs the serial signals in1 through in4 to the primary circuit 2 of the transformer 3.

The serial-to-parallel converter circuit (S/P) 12 converts the time division multiplexed serial signals, received from the retention element 8, into parallel output signals out1 through out4, and outputs the parallel output signals out1 through out4 to the output terminals OUT1 through OUT4.

The parallel-to-serial converter circuit (P/S) 11 and the serial-to-parallel converter circuit (S/P) 12 may be capable of converting the serial signals and the parallel signals. For example, a combination of a shift register and a control circuit, a UART (Universal Asynchronous Receiver Transmitter) circuit, etc. can be employed.

Since the signal isolation circuit 1 according to Embodiment 1 only transmits changes in the input signal in, the logic of the input and the logic of the output may not be the same if the input signal in remains unchanged. According to the present embodiment, since the parallel input signals in1 through in4 are converted by the parallel-to-serial converter circuit P/S into serial signals, the signals input to the primary circuit 2 can be configured to change at all times even if the input signals in1 through in4 for the signal isolation circuit 1B remain unchanged. This can prevent the logic of input and the logic of output of the signal isolation circuit 1B from differing.

Note that control signals such as a clock signal and a latch signal are required to cause the shift register to operate, the signal transmission cannot be performed correctly if the timing is out of synch between the primary circuit 2 and the secondary circuit 4. Regarding the control signals such as a clock signal and a latch signal, the signal isolation circuit 1 may be used to transmit a control signal, generated by the primary circuit 2, to the secondary circuit 4, and transmit a control signal, generated by the secondary circuit 4, to the primary circuit 2.

As described above, minimum necessary elements for the configuration and operation of the signal isolation circuit 1B according to Embodiment 3 have been described where there are four signals. Of course, an increased or reduced number of signals can be employed and appropriate other elements can be added, insofar as the function of the signal isolation circuit 1B is not impaired. Moreover, while the delay element 7, the retention element 8, the parallel-to-serial converter circuit P/S, and the serial-to-parallel converter circuit S/P have been described as being configured with individual parts, they may be configured as an integrated circuit such as an IC, or may be configured with micro controllers, programs on a processor such as a CPU, programmable logic devices (such as PLDs, CPLDs, or FPGA).

### Embodiment 4

FIG. 9 is a diagram depicting a configuration of a signal isolation circuit 1C according to Embodiment 4.

Input terminals IN1, IN2, and IN3 receive parallel, at least one digital input signal in1, in2 and at least one analog input signal in3.

Output terminals OUT1, OUT2, and OUT3 output parallel, at least one digital output signal out1, out2 and at least one analog output signal out3.

The signal isolation circuit 1C includes an analog-to-digital converter (ADC) 13 and a digital-to-analog converter (DAC) 14, in addition to the configuration of the signal isolation circuit 1B according to Embodiment 3. The analog-to-digital converter (ADC) 13 and the digital-to-analog converter (DAC) 14 are electrically insulated from each other.

The analog-to-digital converter (ADC) 13 quantizes and converts the analog input signal in3, input to the input terminal IN3, into multi-bit digital signals, and outputs the multi-bit digital signals as parallel digital signals (bits in parallel) to the parallel-to-serial converter circuit (P/S) 11.

The digital-to-analog converter (DAC) 14 converts some (formed of multiple bits that are in parallel) of parallel digital output signals of the serial-to-parallel converter circuit (S/P) 12 into analog signal out3, and outputs the analog signal out3 to the output terminal OUT3.

If the analog signal needs to be isolated and transmitted, in addition to the digital signals, according to the signal isolation circuit 1C of the present embodiment, the analog signal and the digital signal can be isolated and transmitted simultaneously. In other words, the signal isolation circuit 1C according to the present embodiment can function as a mixed-signal signal isolation circuit.

As described above, minimum necessary elements for the configuration and operation of the signal isolation circuit 1C according to Embodiment 4 have been described where there are one analog signal and two digital signals. Of course, an increased or reduced number of signals can be employed and appropriate other elements can be added, insofar as the function of the signal isolation circuit 1C is not impaired. Moreover, while the delay element 7, the retention element 8 the parallel-to-serial converter circuit (P/S) 11, the serial-to-parallel converter circuit (S/P) 12, the analog-to-digital converter (ADC) 13, and the digital-to-analog converter (DAC) 14 have been described as being configured with individual parts, they may be configured as an integrated circuit such as an IC, or may be configured with micro controllers, programs on a processor such as a CPU, programmable logic devices (such as PLDs, CPLDs, or FPGA).

The presently disclosed embodiments should be considered illustrative in all aspects and do not limit the present disclosure. The scope of the present disclosure is defined by the appended claims, rather than by the above description. All changes which come within the meaning and range of equivalency of the appended claims are intended to be embraced within their scope.

### REFERENCE SIGNS LIST

1, 1A, 1B, 1C signal isolation circuit; 2, 2A primary circuit; 3 transformer; 4 secondary circuit; 5 primary coil; 6 secondary coil; 7 delay element; 8 retention element; 11 parallel-to-serial converter circuit (P/S); 12 serial-to-parallel converter circuit (S/P); 13 analog-to-digital converter (ADC); 14 digital-to-analog converter (DAC); 18 RS flip-flop; BF, BF1, BF2, BF(1), BF(2), BF(3) amplifier element; C1, C2 capacitor; CN1 through CN4 interlayer connection; IN, IN1, IN2, IN3, IN4 input terminal; L1, L2, L3, L4 line pattern; LP low-pass filter; and OUT, OUT1, OUT2, OUT3, OUT4 output terminal.

1. A signal isolation circuit, comprising:
an input terminal to receive a digital input signal;
a primary circuit which includes a delay element for delaying the input signal;
a secondary circuit which includes a retention element, the retention element consisting a digital circuit for retaining a digital output signal;
an output terminal to output the output signal; and
a transformer which includes a primary coil connected to the primary circuit and a secondary coil connected to the secondary circuit, wherein
the primary circuit and the secondary circuit are electrically insulated from each other by the transformer so as to operate at different reference potentials,
the primary coil has a first end which is driven by an input signal and a second end which is driven by an output signal of the delay element, and
an induced voltage of the secondary coil is input to the retention element, and the retention element switches and retains a value of the output signal, based on the induced voltage of the secondary coil,
the retention element outputs a first logical value when the induced voltage of the secondary coil is greater than a positive threshold, outputs a second logical value when the induced voltage of the secondary coil is less than a negative threshold, and retains an output value when the induced voltage of the secondary coil is greater than or equal to the negative threshold and less than or equal to the positive threshold.

2. (canceled)

3. The signal isolation circuit according to claim 1, wherein
the retention element includes:
an RS flip-flop;
a first pull-down resistor connected to a first end of the secondary coil of the transformer;
a second pull-down resistor connected to a second end of the secondary coil of the transformer; and
a RS flip-flop having a set terminal connected to the first end of the secondary coil of the transformer, a reset terminal connected to the second end of the secondary coil of the transformer, and a terminal connected to the output terminal.

4. The signal isolation circuit according to claim 1, wherein
the retention element includes an amplifier element,
an input of the amplifier element receives a voltage at the first end of the secondary coil, and a positive feedback circuit configured by an output of the amplifier element driving a second end of the secondary coil,
the output of the amplifier element is connected to the output terminal.

5. The signal isolation circuit according to claim 4, wherein
the retention element further includes a resistor disposed between the amplifier element and a first end of the secondary coil.

6. The signal isolation circuit according to claim 1, wherein
the delay element includes at least one of a low-pass filter and an amplifier element.

7. The signal isolation circuit according to claim 6, wherein
the amplifier element includes a logic buffer.

8. The signal isolation circuit according to claim 1, wherein
the primary circuit further includes a capacitor disposed between the input terminal and the first end of the primary coil.

9. The signal isolation circuit according to claim 1, wherein
the input terminal receives parallel digital input signals,
the output terminal outputs parallel digital output signals,
the signal isolation circuit further comprising:
a parallel-to-serial converter circuit for converting the parallel input signals into serial input signals and outputting the serial input signals to the primary circuit; and
a serial-to-parallel converter circuit for converting serial output signals, output from the retention element of the secondary circuit, into parallel output signals, and outputting the parallel output signals to the output terminal.

10. The signal isolation circuit according to claim 9, wherein
the input terminal receives at least one digital input signal and at least one analog input signal that are input in parallel, and
the output terminal outputs at least one digital output signal and at least one analog output signal that are output in parallel,
the signal isolation circuit further comprising:
an analog-to-digital converter circuit for converting the analog input signal into parallel digital signals and outputting the parallel digital signals to the parallel-to-serial converter circuit; and
a digital-to-analog converter circuit for converting one of the parallel output signals of the serial-to-parallel converter circuit into analog signals and outputting the analog signals to the output terminal.

11. The signal isolation circuit according to claim 1, wherein
the transformer is configured of a pattern for a printed circuit board.
